(19) United States
(12) Patent Application Publication
(10) Pub. No.: US 2004/0250750 A1
(43) Pub. Date: Dec. 16, 2004

(54) Functionalised nanoparticle films

(76) Inventors: Torsten Reda, New South Wales (AU); Geoffrey Raymond Baxter, New South Wales (AU)

Correspondence Address: NIXON & VANDERHYE, PC, 1100 N GLEBE ROAD, 8TH FLOOR, ARLINGTON, VA, 22201-4714, US

(21) Appl. No.: 10/487,459

(22) PCT Filed: Aug. 26, 2002
(86) PCT No.: PCT/AU02/01134

(30) Foreign Application Priority Data
Aug. 24, 2001 (AU) PR7257

(51) Int. Cl. C30B 23/00; C30B 25/00; C30B 28/12; C30B 28/14

(52) U.S. Cl. 117/84

(57) ABSTRACT

The present invention provides a method for preparing stable sols of surface-modified nanoparticle aggregates. The methods involves the steps of: (i) producing a sol of nanoparticles; (ii) adding at least one functionalising agent to the sol of nanoparticles; (iii) allowing the nanoparticles and the at least one functionalising agent to react to form a sol of surface-modified nanoparticle aggregates; and (iv) purifying the sol of surface-modified nanoparticle aggregates to obtain a purified sol of surface-modified nanoparticle aggregates in which the aggregates are of a size range of about 4 nm in diameter and greater than about 10 μm in diameter.

### FIELD OF THE INVENTION

The present invention relates generally to the preparation of highly concentrated and stable sols of surface-modified small nanoparticle aggregates, and to methods for using such concentrates to prepare films containing variable ratios of one or more types of functionalising compounds separating or linking the nanoparticles, where such methods include printing, spraying, drawing and painting.

### BACKGROUND OF THE INVENTION

In the past decade, nanostructured materials in general and nanoparticles in particular have become the focus of intensive research activities. The myriad of materials that have been used to produce nanoparticles include metals, e.g. Au, Ag, Pd, Pt, Cu, Fe, etc; semiconductors, e.g. TiO₂ CdS, CdSe, ITO, etc; insulators e.g. SiO₂ magnetic materials, e.g. Fe₂O₃, Fe, Ni, etc; superconductors, organic compounds etc. The combination of these particles with organic and inorganic molecules opens up a nearly unrestricted number of possibilities to build new materials. On one hand, after their synthesis the particles can be functionalised with organic molecules [DUFF DG ET AL., 1993; SARATHY KV ET AL., 1997] or inorganic compounds [ALEJANDRO-ARELLANO M ET AL., 2000]. On the other hand, organically functionalised metal nanoparticles can be produced by mixing a metal precursor with an organic'surface passivant and reacting the resulting mixture with a reducing agent to generate free metal while binding the passivant to the metal surface [YONEZAWA T AND KUNITAKE T, 1999]. These solutions, however, are too dilute and not pure enough to be useful directly as inks for the deposition of coherent films by printing, spraying, drawing and painting.

Ink jet printing of CdSe nanoparticles was described, for the first time, by Ridley BA ET AL. [1999]. In general, JACOBSON J ET AL. [2000] describe this process for nanoparticles in general. Their invention utilises nanoparticles to create, through print deposition and patterning, functional electronic, electromechanical, and mechanical systems. Furthermore, they mention the concept of passivating the surface of nanoparticles by an organic shell, which surrounds inorganic particle core. Specifications for the necessary nanoparticles processing are not given.

Examples for concentrates of functionalised nanoparticles are disclosed in HEATH JR AND LEFF DV [2000], who describe methods of producing organically functionalised metal nanoparticle powders, which are directly resoluble as monodisperse nanocrystals only in organic solvents for concentrations up to 30 mg/ml. “Monodisperse” describes in this context individual nanoparticles. Most of the organic solvents, however, cannot be used in commercial printing applications. They describe the concept of solubilisation in aqueous media by adding soap or detergent to the water phase, which captures the functionalised nanoparticles upon entering. Only “non-cross-linking” agents can be used for this processing, and the surface passivant has to be added to the metal precursor before a reducing agent to generate the metal.

A number other techniques have been published concerning the preparation of more or less well-defined layered structures made from nanoparticle-organic/inorganic molecule composites.

Evaporation of colloidal gold solution droplets deposited onto substrates has produced ill-defined structures [SCHMID G ET AL., 1990]. Electrophoretic deposition taking advantage of the charge surrounding the nanoparticles in solution has been used to produce films [GIERSIG M AND MULVANEY P, 1993]. The film properties, however, are difficult to control, the films are cracked, and the process requires conducting substrates. Bulk structures have also been produced by cross-linking nanoparticles with organic linker molecules, allowing the aggregates to precipitate, then compressing the bulk material into pellets [BRUST M ET AL., 1995]. The layer-by-layer method is based on a step-by-step formation of thin films by alternatively adding cross-linking molecules and nanoparticles [BRUST M ET AL., 1998; MUSICK MD ET AL., 1999; FENDLER JH, 1996]. The slow binding kinetics and the washing steps necessary after each every step results in a very time consuming and labour intensive procedure. The molecule between the nanoparticles has to have the ability to bind and link the nanoparticle, and the substrate requires special treatment. The proposed one-step exchange cross-linking precipitation method [LEIBOWITZ FL ET AL., 1999] may be difficult to control. The nanoparticles precipitate most likely as superlattices and not as coherent thin film structures. RAGUSE B AND BRAACH-MAKSVYTIS VLB [2001] describe three-dimensional array films using cross-linked nanoparticles. The film formation is typically on nanoporous membrane substrates and the subsequent transfer of the films can be difficult. The method disclosed by KIM K AND FENG Q [1999] produces deposits by electrostatic spraying of nanodroplets of a working liquid, which contain base compounds (e.g. metal-trifluoroacetate) in suitable solvents (e.g. methanol) as described earlier in KIM K AND RYU CK [1994]. Electric charges applied to the liquid cause disruptions of the surface and form small jets, breaking up into charged liquid clusters. Solid metal and metal oxide nanoparticles can be formed by solidification of the nanodroplets. Functionalising with capping molecules is not possible. The method disclosed by SCHULZ ET AL. [2000] uses metal chalcogenide nanoparticles in combination with volatile capping agents to produce semiconductor nanoparticles and, more specifically, produces mixed-metal chalcogenide precursor films via spray deposition. This method is limited to the usage of organic solvents. The presence of water in the colloidal suspension causes destabilisation, agglomeration and colloid decomposition. The method disclosed by SPANHEL L ET AL. [1995] produces composite materials that contains precipitated nanoscaled antimonides, arsenides, chalcogenides, halogenides or phosphides of various metals. Bifunctional compounds are added which exhibit at least one electron pair-donor group and at least one group, which can be converted through polymerisation or polycondensation into an organic or inorganic network. For the immobilisation, the nanoparticle solution is mixed with polymerisable compounds and a polymerisation initiator to form a network containing nanoparticles. Core/shell type nanocrystals combined with polymers are used in different combinations for film depositions of CdSe [SCHLAMP MC ET AL., 1997; GREENHAM NC ET AL., 1997; CASSAGNEAU T ET AL., 1998]. Ink-jet patterning of colloidal suspensions of Pt nanoparticles was used by SHAH P ET AL. [1999] to deposit Pt as catalysts onto polymer surfaces for the electroless deposition of copper. The Pt patterns are black and non-conductive.

In general, inks, e.g. for ink jet printers, contain organic pigments. They can also be prepared with nanometer sized inorganic pigments based on carbides, nitrides, borides and silicides [GONZALEZ-BLANCO J ET AL., 2000], which are typically produced in powder form. The preparation of these inks includes the addition of different dispersants with an average molecular weight >1000, and of water. Metal powders with particle sizes in the micrometer range [GRUBER ET AL., 1991; YOSHIMURA Y ET AL., 2001] and their combinations with different varnishes, waxes and solvents [LYEN EA, 2000] are the main ingredients of metallic inks.

None of the methods mentioned thus far is able to solve the problem of preparing coherent functionalised nanoparticle film structures for a wide variety of nanoparticles, functionalising agents and supporting substrates. By chemical synthesis from metal salts and reducing agents only low-concentration nanoparticle solutions can be prepared. In addition, the solvent contains counter ions and often pollutants. If surfactants and capping reagents are added, their excess molecules remain in solution as well. When the solvent evaporates or migrates into the substrate surface, non-homogeneous nanoparticle aggregates are formed with salt, pollutant and excess molecules interspersed between aggregates, that prevent films or other ordered structures from being formed. The difference between the surface tensions of the solid, liquid and gas phases is most likely to be large enough for the liquid film to tear or to forms droplets if the evaporation does not occur quickly enough. Attempts to increase the concentration by evaporating the solvent using heat or vacuum do not solve the problem of removing the salt and excess molecules. Furthermore, the nanoparticles start to aggregate and precipitate.

### SUMMARY OF THE INVENTION

In a first aspect the present invention consists in a method for preparing stable sols of surface-modified nanoparticle aggregates, the methods comprising the steps of:

(i) producing a sol of nanoparticles;

(ii) adding at least one functionalising agent to the sol of nanoparticles;

(iii) allowing the nanoparticles and the at least one functionalising agent to react to form a sol of surface-modified nanoparticle aggregates; and

(iv) purifying the sol of surface-modified nanoparticle aggregates to obtain a purified sol of surface-modified nanoparticle aggregates in which the aggregates are of a size range of about 4 nm in diameter to about 10 μm in diameter.

In a further aspect the present invention consists in a method of forming a coherent film comprising surface-modified nanoparticle aggregates, the method comprising depositing a sol of surface-modified nanoparticle aggregates produced according to the method of the first aspect of the present invention.

In a still further aspect the present invention consists in an ink comprising a stable sol of surface-modified nanoparticle aggregates, the sol being produced according to the method of the first aspect of the present invention.

As used herein the term “sol” means a liquid solution or suspension of a colloid.

As used herein the term “purified” means that excess functionalising agent, salt ions and other impurities are substantially removed from the sol.

### BRIEF DESCRIPTION OF FIGURES

FIG. 1

Temperature dependence of the electrical resistance of functionalised nanoparticle films based on 18 nm Au/4-NTP concentrate sprayed on Epson ink jet transparency using a Paasche airbrush. The films were continuously heated in a furnace up to a maximum temperature Tₘₐₓ. One of the films was heated to Tₘₐₓ₌150° C. and subsequently furnace-cooled (black curve), while the other film was heated to Tₘₐₓ₌240° C. (grey curve). Note the logarithmic resistance scale.

FIG. 2

Evolution of the electrical resistance of a functionalised nanoparticle film based on 18 nm Au/4-NTP concentrate printed on Epson ink jet transparency using a Canon-2100 SP printer under selective irradiation. The sample was exposed to three pulses of white light generated using a commercial flashlight. The insert shows details of the behaviour during the second light pulse.

### DETAILED DESCRIPTION

The present invention provides various highly concentrated solutions of nanoparticles functionalised with organic or inorganic compounds and methods for their production. These methods are based on an all-wet preparation procedure resulting in stable aqueous or organic polydisperse sols of small nanoparticle aggregates. In addition, the present invention provides methods to deposit coherent films and multilayers consisting of such films from said concentrates on rigid or flexible substrates. Furthermore, the present invention provides of methods to selectively modify the properties of the film material by local sintering or melting. Furthermore, the present invention provides devices based on the properties of said functionalised nanoparticle films.

### Nanoparticle Preparation and Functionalising

Solutions of nanoparticles based on metals, e.g. Au, Ag, Pd, Pt, Cu, Fe, etc; alloys, e.g. CoₓAu_{y}, semiconductors, e.g. TiO₂ CdS, CdSe, ITO, etc; insulators e.g. SiO₂, magnetic materials, e.g. Fe₂O₃, Fe, Ni, etc; superconductors, organic compounds etc. can be prepared using a variety of methods described in the literature. These sols are mixed with another solution containing functionalising agents which can be organic or inorganic compounds. These molecules start to cross-link the nanoparticles and form a densely packed shell around the nanoparticles until the outer shell around the nanoparticle aggregates is densely packed, preventing further aggregation of the nanoparticle aggregates. Important herein is that the process is not limited anymore to solutions of functionalised individual nanoparticles. In addition, the formation of small aggregates provides significant advantages in the further processing and concentration. The concentrations of the functionalising agents and nanoparticles, respectively, stirring rate and temperature are important parameters to control this process. Ultrasonic activation may be used to limit the growth of aggregates before the passivating shell is formed on the surface of the aggregates.

The capping compounds can be charged, polar or neutral. They include inorganic ions, oxides and polymers as well as organic aliphatic and aromatic hydrocarbons; organic halogen compounds, alkyl, alkenyl, and alkynyl halides, aryl halides; organometallic compounds; alcohols, phenols, and ethers; carboxylic acids and their derivatives; organic nitrogen compounds; organic sulfur compounds; organic silicon compounds; heterocyclic compounds; oils, fats and waxes; carbohydrates; amino acids, proteins and peptides; isoprenoids and terpenes; steroids and their derivates; nucloetides and nucleosides, nucleic acids; alkaloids; dyes and pigments; organic polymers, including insulating, semiconducting and conducting polymers; fullerenes, carbon nanotubes and fragments of nanotubes.

The possibilities to combine a particular nanoparticle with a capping agent are manifold. The capping agent can adsorb onto the nanoparticle surface or form coordinative bonds. Certain compounds which, when used in lower and middle concentrations, usually cross-link and thus extensively aggregate and precipitate the nanoparticles, form densely packed protecting shells around small aggregates of nanoparticles if the concentration is high enough. This behavior is observed, e.g., for dithiols reacting with Au nanoparticles.

If functionalising agents are used which tend to form large nanoparticle aggregates, ultrasound, radiofrequency waves, heat or other types of energy may be applied to the solution for limiting the growth of aggregates or to subsequently break down larger aggregates into smaller sizes.

Furthermore, using photo-cross linking or photo-cross clearing agents can control the size of the functionalised nanoparticle aggregates if combined with appropriate light doses. Such compounds are for example pyrimidine or coumarin derivatives. If functionalising agents like peroxides, azo-compounds etc. are used nanoparticles can cross-link via free radical reaction. The amount of oxygen or other terminator compounds can control the growth of aggregates. Additionally, linker lengths may become modified during this type of aggregation by using such initiator molecules in combination with polymerizable compounds like ethylenes, styrenes, methyl methacrylates, vinyl acetates or others.

### Concentration of the Functionalised Nanoparticle Aggregates

The sol of small nanoparticle aggregates is concentrated once or repeatedly by centrifugation, precipitation, filtration (e.g. using nanoporous membranes) or dialysis. This step removes nearly all residual molecules like salt ions, pollutants, excess functionalising agent, and most of the solvent. If necessary, several washing steps can be added. At the same time, the nanoparticle sols are purified by removing smaller-sized particles and/or larger aggregates which may be present due to impurities. In some instances pellets or precipitates may need to be redissolved in appropriate solvents, if necessary supported by ultrasonic activation. The nanoparticle concentrate is stable on a time scale of days up to months.

In this context, the formation of small nanoparticle aggregates by using suitable combinations of functionalising agents reveals its real importance. On one hand, individual functionalised nanoparticles of only a few nanometers in size (less than about 4 nm) are often too small to be concentrated within reasonable times even using ultracentrifuges which can only take low volumes at a time. The controlled formation of small aggregates simplifies the procedure of concentrating the nanoparticles significantly. On the other hand, nanoparticle aggregates of larger sizes (greater than about 10 μm in diameter) do not form coherent structures of densely packed functionalised nanoparticles. Furthermore, such type of nanoparticle aggregates cannot be used in thin film deposition methods described below, especially when microsized valves and nozzles are used to direct the flow of the concentrates.

### Thin Film Deposition

The concentrates of functionalised nanoparticle aggregates can be used to deposit coherent films on rigid or flexible substrates. The deposition onto an appropriate surface can be carried out by spraying the concentrate as an aerosol or in the form of individual droplets, or by printing, drawing and painting. The residual solvent evaporates or migrates into the substrate. Alternatively, deposition may be facilitated by electrophoretic or dielectrphoretic techniques. The growing film is homogeneous with regard to the functionalising molecules.

Appropriate surfaces include high quality papers, plastics like ink jet transparencies, glass, metals and others. It may also be advantageous to treat the surface before deposition with respect to smoothness, hydrophilicity or surface tension and solvent absorbing properties. For water-based concentrates, hydrophilic surfaces are preferable, and a capability to bind and remove some water is useful. In addition, droplet size, feed rate, temperature and humidity play a crucial role.

One or more additional compounds may be added, in solid, liquid or vapour form, to the concentrate at an appropriate stage in the deposition process. These compounds can be chosen from the range of capping agents outlined above. The molecules may be chosen to have the ability to exchange with, penetrate into, cross-link or bind to the protectant shell or to the nanoparticle. The growing film is now non-homogenous with regard to the functionalising molecules. The exchange reaction between thiolates bound to gold and free thiols in a solution is controlled by a number of reaction parameters, which were demonstrated by introducing various functionalised components into the shell structure [HOSTETLER ET AL., 1996; TEMPLETON ET AL., 1998].

Furthermore, using the film formation process as outlined above as a starting point, multilayer structures can be produced by sequentially depositing films using the same or different nanoparticle concentrates. In this manner, three-dimensional structures can be formed. In addition, layers of other materials like organic polymers can be readily integrated into such structures.

The functionalised nanoparticle films may be patterned both during deposition, e.g. as part of the printing, spraying, drawing or painting process, or subsequently, for instance by lithographic etching or liftoff techniques.

In order to provide protection for the nanoparticle film a protective layer consisting of, e.g., a polymer coating can be applied to the surface of the film.

### Annealing, Sintering and Melting by Selective Irradiation

It is often desirable to modify the properties of films in a controlled fashion after deposition. Literature results [FISHELSON N ET AL., 2001; SANDHYARANI N ET AL., 2000; WUELFING WP ET AL., 2000] indicate that the melting point of nanoparticles (e.g. CdSe, Au, Ag) may be dramatically reduced compared to the bulk material. We have found that by selectively activating nanoparticle film material using electromagnetic irradiation, partial or complete annealing, sintering or melting of the material in the irradiated area can be achieved. This modification of the structure of the film results in profound changes of its physical properties. Most prominent is an increase of the electrical conductivity and associated changes in related properties, e.g. optical reflectivity. By varying the irradiation parameters such as power, wavelength, duration etc. and appropriate selection of the targeted area, e.g. by masking, the conduction properties of nanoparticle films can be tuned locally.

### Applications

The mechanical, electronic, optical, thermal, chemical and other properties of both the nanoparticles and the capping and/or cross-linking compounds and their combinations open up a large variety of applications for films produced from such constituents. Furthermore, the change of these properties in response to external stimuli can form the base for sensors and switchable and/or self-adapting devices. Examples for such stimuli include, but are not limited to, changes in mechanical stress, pressure, electromagnetic fields including light, temperature, or chemical environment. Some of these applications are outlined below:

(i) The nanoparticle concentrate can be used for depositing functionalised nanoparticle films which are sensitive to mechanical stress and would function as sensitive strain gages.

(ii) The nanoparticle concentrate can be used for depositing functionalised nanoparticle films which form stable, metallic and highly reflecting coatings for decorative purposes. In addition, the shiny and metallic appearance of such coatings cannot be reproduced using conventional copying techniques, making them effective as anti-counterfeit features in identification structures on documents, notes and other valuables.

(iii) The nanoparticle concentrate can be used for depositing functionalised nanoparticle films which form stable, metallic and highly reflecting coatings which can be modified subsequently by imprinting or embossing structures with typical length scales ranging from nanometers to centimetres. Applications of these modified films range from decorative coatings to highly effective anti-counterfeit identification structures.

(iv) The nanoparticle concentrate can be used for depositing functionalised nanoparticle films which are sensitive to the presence of particular compounds and would function as chemical sensors.

(v) The nanoparticle concentrates can be used for depositing multi-layer structures consisting of layers of metal nanoparticles functionalised with electron donors, layers of polymers or polymer nanoparticles functionalised with pigments, and layers of metal nanoparticles functionalised with electron acceptors. Such structures would form a new type of photovoltaic device.

(vi) The nanoparticle concentrate can be used for depositing functionalised nanoparticle films which can be patterned and whose electrical properties can be modified by selective irradiation. In this manner, passive electronic components, such as resistors, capacitors, inductors etc. and highly conducting interconnections between these components can be produced, thus forming printed circuits with integrated components. Applications for such circuits are manifold and include transformers, resonators, antennas etc. Sequential application of selective irradiation can be used to program analog or digital memory.

### Scheme for the Preparation of Functionalised Nanoparticle Concentrates

A general method for the preparation of functionalised nanoparticle aggregate concentrates involves the synthesis of nanoparticle solutions, mixing these solutions with solutions of functionalising agents, and concentrating the resulting mixtures. Various combinations of functionalisation and concentration procedures based on different types of functionalising agents are classified as follows:

F1 Functionalising Agent with one Binding Site (Capping Agent).

F1.1 Functionalising agent completely surrounds each individual nanoparticle, protecting the nano-particle against aggregation. Subsequently, compounds with the ability to exchange with, penetrate into, cross-link or bind to the protectant shell or to the nanoparticle are added, which form small aggregates of these nanoparticles. Similar results can be achieved with mixtures of the capping and cross-linking agents (see also F2.2). Under circumstances, weak interactions between the capping agents themselves may result in the formation of small aggregates during the following process of concentration.

F1.2 Functionalising agent forms micelles or similar structures in the solvent, where the binding sites are exposed to the micelle surface. Thus, the micelles effectively act as functionalising agents with two or more binding sites, aggregating the nanoparticles. For further description and subsequent processing see case F2.

F2 Functionalising Agent with two or More Binding Sites (Cross-Linking Agent).

F2.1 At high concentrations of the functionalising agent, the binding to the nanoparticle surface proceeds at a rate high enough for a dense shell to surround each individual nanoparticle before cross-linking to another particle can occur. Subsequently, compounds with the ability to exchange with, penetrate into, cross-link or bind to the shell or to the nanoparticle are added, which form small aggregates of these nanoparticles. Similar results can be achieved with mixtures of the capping and cross-linking agents (equivalent F1.1). Under some circumstances, weak interactions between the capping agents themselves may result in the formation of small aggregates during the following process of concentration.

F2.2 At intermediate concentrations of the functionalising agent, the molecules cross-link the nanoparticles to form nanoparticle aggregates which increase in size until a dense shell is formed around each aggregate, preventing further growth. Stopping the aggregates against further growth can be enhanced by adding a capping agent or mixing directly cross-linking with capping agents (compare F1.1.).

At low concentrations of the functionalising agent, the molecules cross-link the nanoparticles to form nanoparticle aggregates which increase in size. The aggregates form larger (greater than about 10 μm in diameter), solid super-structures, which are unsuitable for use in this invention.

C1 The sol of small nanoparticle aggregates is concentrated by centrifugation, filtration (e.g. using nanoporous membranes), or dialysis. Using centrifugation, the nanoparticle sol can be split into three fractions: a pellet containing impurities of larger aggregates, the desired nanoparticle concentrate, and the supernatant with smaller individual nanoparticles, salt and other excess molecules. Alternatively, the nanoparticle solution can be concentrated by filtration, e.g. using nanoporous filter membranes with pore sizes comparable to the size of the nanoparticle aggregates. This concentration step removes nearly all residual molecules such as salt ions, pollutants, excess molecules of the functionalising agent, and most of the solvent. If necessary, this concentration procedure can be repeated a number of times after adding solvent to the concentrate obtained in the previous concentration step.

C2 If small nanoparticle aggregates are formed which precipitate, the precipitate itself can be washed by repeated resuspension and precipitation and used afterwards as concentrated colloid suspension of nanoparticle aggregates. If required, the precipitate can be resuspended or dissolved into other appropriate solvents, if necessary assisted by ultrasonic activation.

These procedures result in concentrates of nanoparticle aggregates which are polydisperse, i.e. contain aggregates of differing numbers of nanoparticle, and which are stable on a time scale of at least days up to months.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

All publications mentioned in the specification are herein incorporated by reference.

Any discussion of documents, acts, materials, devices, articles or the like which has been included in the present specification is solely for the purpose of providing a context for the present invention. It is not to be taken as an admission that any or all of these matters form part of the prior art base or were common general knowledge in the field relevant to the present invention as it existed in Australia before the priority date of each claim of this application.

In order that the nature of the present invention may be more dearly understood preferred forms thereof will be described with reference to the following Examples.

### Methods and Examples

All the nanoparticle concentrates described below are based on gold or silver nanoparticles, which were prepared in water as the solvent, by using published methods [TURKEVICH J ET AL. 1951; CRAIGHTON JA ET AL. 1979]. The resulting solutions of nanoparticles are highly dilute (e.g. for the gold and silver nanoparticles,

typical concentrations are between 30 and 60 μg/ml) and relatively stable; however, many exhibit oxidation and aging effects.

The solvents of the nanoparticle solutions and of the solution of functionalising agents have to have the ability to mix well with each other, e.g. water with dimethylsulfoxide (DMSO), water with ethanol etc. DMSO is a universal solvent due to its high solubility both in water and in organic solvents. Thus, DMSO can transfer nearly all functionalising compounds into the aqueous nanoparticle solutions.

Combinations of Au or Ag nanoparticles with functionalising agents containing thiols or disulfides as binding groups are particularly effective. However, other similar functionalising compounds containing nitrogen, charges, hydrophilic or hydrophobic groups etc. can be used.

The following examples illustrate the various classifications described above:

### Example Functionalisation of Nanoparticles 1.1

100 ml aqueous solution of gold nanoparticles (size ˜18 nm) are functionalised with a capping layer consisting of 4-nitrothiophenol (4-NTP) by adding 100 μl of 100 mM 4-NTP dissolved in DMSO. Alternatively, negatively charged molecules, e.g. adds such as mercaptoacetic or dithioglycolic acid, electron acceptors like tetracyanoquinodimethan (TCNQ), or pigments such as 4-(4-nitrophenolazo-) resorcinol (Magneson) can be used. The formation of aggregates occurs during the step of concentration, where centrifugation is used to compress and consequently cross-link the functionalised nanoparticles into small aggregates.

### Example Functionalisation of Nanoparticles and Forming Aggregates 1.2

100 ml aqueous solution of gold nanoparticles (size ˜18 nm) are functionalised with a capping layer consisting of 4-nitrothiophenol (4-NTP) by adding 100 μl of 100 mM 4-NTP dissolved in DMSO. Alternatively, negatively charged molecules, e.g. acids such as mercaptoacetic or dithioglycolic acid, electron acceptors like tetracyanoquinodimethan (TCNQ), or pigments such as 4-(4-nitrophenolazo-resorcinol (Magneson) can be used. The controlled aggregation is introduced by adding cross-linking agents like octanedithiol dissolved in DMSO with a final active concentration of several μM. Alternatively, carboxyacid capping layers can be chemically linked via diamines or via charge complexes introduced by dications. Instead of capping and subsequently cross-linking the nanoparticles into small aggregates, similar results might be achieved by using mixtures of capping agents like 4-nitrothiophenol (4-NTP) and cross-linking agents like octanedithiol. The concentration of the cross-linking agent has to be several magnitudes lower than the concentration of the capping agent.

### Example Functionalisation of Nanoparticles and Forming Aggregates 1.3

100 ml aqueous solution of gold nanoparticles (size ˜18 run) are cross-linked with micelles of propanethiol by adding 100 μl of 100 mM propanethiol dissolved in DMSO. Alternatively, ethanethiol or alkyl thiols with longer chain lengths or other amphiphilic chemicals can be used.

### Example Functionalisation of Nanoparticles and Forming Aggregates 2.1

100 ml aqueous solution of gold nanoparticles (size ˜18 nm) are functionalised with a capping layer consisting of butanedithiol by adding 100 μl of 10 M butanedithiol dissolved in DMSO resulting in an active final concentration (c_{f}) of 10 mM. If concentrations cᵢ between100 μM and 1 mM are used, ultrasonic activation is necessary to limit the growth of aggregates to small sizes. Concentrations c_{f} below 1 μM form small aggregates where the nanoparticle are linked but not completely separated. The nanoparticles are touching each other and structures made out of them are metallic conductive. Alternatively, other alkyl dithiols and dithiols in general at appropriately high concentrations can be used. If the nanoparticles are capped completely with such dithiols they can be linked afterwards via disulfide bridges introduced by oxidation using peroxides or oxygen as well as using oxidized dithiothreitol in low concentrations.

### Example Functionalisation of Nanoparticles and Forming Aggregates 2.2

100 ml aqueous solution of gold nanoparticles (size ˜18 run) are cross-linked with ethanedithiol by adding 100 μl of 100 mM ethanedithiol dissolved in DMSO (c_{f} 100 μmM). Rigorous stirring is necessary, however, ultrasonic activation is even more effective. If c_{f}'s of more than 1 mM ethaneditiol are used, no additional activation is necessary to limit the aggregate size. Concentrations c_{f} below 1 μM form small aggregates where the nanoparticle are linked but not completely separated. When the nanoparticles are touching each other, the structures made out of them are metallic conductive. Alternatively, other alkyl dithiols, positively charged molecules such as amines like thiourea or cystamine, electron donors like tetramethyl-p-phenylenediamine (TMPD), pigments such as zinc,5,10,15,20-tetra-(4-pyridyl-)21H-23-H-porphine-tetrakis(methchloride) (Zn-porphine) or diphenylthiocarbazone (dithizone) can be used.

For homogenous functionalising as described in these examples, rapid mixing by stop flow injection and rigorous activation by stirring or ultrasound is preferred.

Large, solid superstructures are obtained by mixing (without rigorous activation) 100 ml aqueous solution of gold nanoparticles (size ˜18 nm) with 100 μl of 100 mM 4-mercaptophenol dissolved in DMSO. Alternatively, 6-mercaptopurine or others can be used. Such superlattices cannot be used for film depositions described later, only as nanoparticle crystals themself. However, they can be broken up into small aggregates by using high energetic ultrasound.

### Example Nanoparticle Concentration and Forming Aggregates 3

(a) 500 ml of 18 nm Au/4-NTP nanoparticle solution prepared according to example 1.1, were concentrated to 22 ml using a high-speed centrifuge (Beckman J2-21, rotor JS 10, 20 min, 16000 g, 10° C.). A second concentration step was carried out to concentrate the 22 ml of solution to 8 ml using a Sigma 3K18C centrifuge (10 min, 15000 g, 10° C.). In a third concentration step (Sigma 3K18C, 10 min, 12000 g, 10° C.), the final volume of 325 μl of functionalised nanoparticle concentrate was obtained. The concentration factor was approximately 440 with a final gold concentration of 21 mg Au/ml. In another experiment, a concentration factor of 3243 corresponding to a gold concentration of 155.7 mg Au/ml was achieved. This process yielded polydisperse functionalised nanoparticle aggregate concentrates due to compressive forces during the centrifugation. They can be stored for months at 4° C. and even room temperature without significant changes.

(b) Using a centrifugation procedure similar to (a), a 18 nm Au/Magneson nanoparticle solution was concentrated 227 times, with a final gold concentration of 10.9 mg Au/ml. A 18 nm Au/TCNQ nanoparticle solution was concentrated 210 times with a final gold concentration of 10.1 mg Au/mil. Furthermore a 18 nm Au/dithioglycolic acid nanoparticle solution was concentrated 44 times with a final gold concentration of 2.1 mg Au/ml. This process yielded polydisperse functionalised nanoparticle aggregate concentrates due to compressive forces during the centrifugation. They can be stored for months at 4° C. and even room temperature without significant changes.

(c) Using a centrifugation procedure similar to (a), a 10 nm Ag/4-NTP nanoparticle solution was concentrated 130 times, with a final silver concentration of 3.5 mg Ag/ml. A 50 nm Ag/4-NTP nanoparticle solution was concentrated 85 times, with a final silver concentration of 5.3 mg Ag/ml. A 50 nm Ag/citrate nanoparticle solution was concentrated 77 times, with a final silver concentration of 4.8 mg Ag/ml.

All these concentrates consist of small polydisperse aggregates.

### Example Nanoparticle Aggregate Concentration 4

(a) 10 ml of 18 nm Au/ethanethiol nanoparticle solution prepared according to example 1.3 were concentrated to 1 ml by precipitating the aggregates that had formed, washing several times with water and ethanol, and dissolving them in dichlormethane (DCM) assisted by ultrasonic activation. This process yielded a polydisperse functionalised nanoparticle concentrate which can be stored for months at 4° C.

(b) 500 ml of 10 nm Ag/thiourea nanoparticle solution prepared according to example 2.2 were concentrated to 1 ml by precipitating the aggregates that had formed and washing several times with water. This process yielded a polydisperse aqueous functionalised nanoparticle concentrate which can be stored for months at 4° C.

### Film Deposition Cross-Linker Exchange and Patterning

The functionalised nanoparticle concentrates can be used similar to conventional inks in ink jet printers, droplet injectors, airbrushes, drawing or mapping pens, as well as in other printing techniques to form coherent films on suitable substrates.

In the examples described below, 18 nm Au/4-NTP nanoparticle concentrate prepared according to E C1 were diluted with Milli-Q water to a concentration of 0.4 mg Au/ml. An ink jet printer (Canon BJC-210SP, Canon Inc., USA), airbrushes (V Shipon feed, double action, internal mix, Paasche Airbrush Co., Harwood Heights IL., USA; Iwata HP-A, double action, Medea Airbrush Products, Portland OR., USA), a Rotring drawing pen (Rotring rapidograph, 0.25 mm, Sanford GmbH, Hamburg, Germany), and various mapping pens were used to transfer the concentrate onto flexible plastic substrates to form coherent thin films.

Using ink jet printers or airbrushes, the nanoparticle concentrate can be transferred layer by layer to achieve a desired film thickness.

One or more additional compounds, e.g. cross-linking agents, can be mixed with the concentrate. For example, 1 mM butanedithiol dissolved in DMSO was added to the 18 nm 4-NTP/Au nanoparticle concentrate in the ratio 1/100 directly inside the ink reservoir of a mapping pen. The resulting films exhibit a colouring significantly different from that observed for the films deposited from 18 nm 4-NTP/Au nanoparticle concentrate alone. This change may be an indication of possible cross-linking of the nanoparticles following the exchange of 4-NTP capping molecules by butanedithiol cross-linker molecules.

During spray deposition, patterning of the nanoparticle film can be achieved using shadow masks. When using ink jet printing, patterning can be performed conveniently by sending appropriate control sequences to the printer using a computer. Multi-layer structures can also be produced by sequential deposition of nanoparticle films. Using shadow masks it is possible to define various patterns such as vertical and horizontal strips, etc. Similar structures can be obtained by sequential ink jet printing.

### Annealing, Sintering and Melting by Selective Irradiation

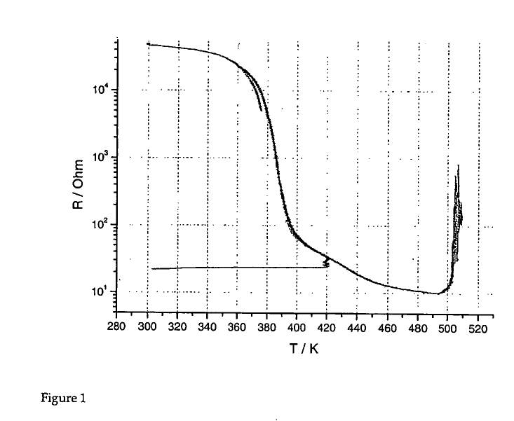

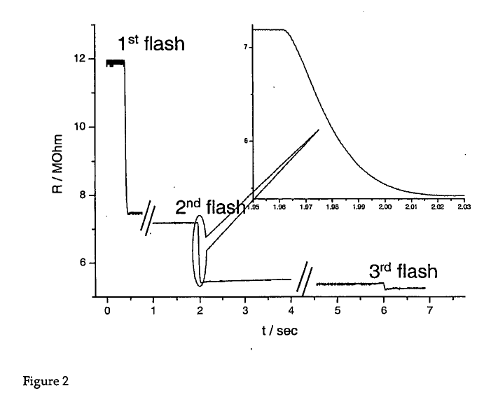

The optical, electrical, thermal and mechanical properties of the nanoparticle films can be modified by selectively exposing them to heat or electromagnetic radiation. One method to achieve this purpose is the controlled application of heat to the entire film, e.g. in a furnace. FIG. 1 shows the temperature dependence of the electrical resistance of films based on 18 nm Au/4-NTP nanoparticle concentrate prepared according to example 3 which were deposited on Epson ink jet transparencies using spray deposition. As the temperature is increased from 20° C. to ca. 150° C., the resistance drops dramatically by about three orders of magnitude. This change is irreversible, and the resistance retains its low value upon subsequent cooling. When the temperature was increased to 240° C., the substrate started to decompose, and the film resistance increased in an uncontrolled fashion. Alternatively, electromagnetic radiation can be applied in relatively short bursts or pulses, e.g. by flashing light onto the nanoparticle film. FIG. 2 illustrates a typical response of a film produced from an 18 nm Au/4-NTP nanoparticle concentrate prepared according to example 3 which was deposited on Epson ink jet transparencies using spray deposition. The film was exposed to three pulses of white light produced by a flash lamp. In response to the irradiation, the electrical resistance of the film decreased significantly, with the relative change decreasing for each subsequent flash event. The typical time scale of the response was 100 ms. Selective irradiation not only reduces the resistance of the nanoparticle films, but also changes the character of the electrical conduction from tunneling to ohmic, as manifested particularly dearly in the low-temperature behaviour of the electrical resistivity. This change is associated with the partial or complete removal of the functionalising agents separating the nanoparticles which form tunneling barriers in the unirradiated films.

### Other Modifications of The Functionalised Nanaparticle Films

The 18 nM Au/4-NTP nanoparticle films exhibit different optical reflectivities and electrical conductivities depending on the substrate. As a consequence of the film thickness, the film can appear semitransparent, coloured or highly reflective metallic golden (or silver when using 10 nm Ag/4-NTP nanoparticle films). When used as metallic ink, these nanoparticle concentrates can be printed to form long-lasting metallic images with a bright and shiny appearance. If necessary, annealing, sintering or melting by selective irradiation can increase the reflectivity and durability of the film. Furthermore, these films can be modified by imprinting or embossing.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

### References

| Patent | Inventor(s) | Applicant |
|---|---|---|
| WO 01/25316 | Raguse B and Braach-Maksvytis | CSIRO |
| | VLB | |
| U.S. Pat. No. | Yoshimura Y, Murata N, Shibuya | Sakura Color |
| 6171381 | K, Matsumoto K, | Products |
| | | Corporation |
| U.S. Pat. No. | Schulz DL, Curtis CJ, Ginley DS | Midwest |
| 6126740 | | Research |
| | | Institute |
| U.S. Pat. No. | Gonzalez-Blanco J, Hoheisel W, | Bayer |
| 6110266 | Nyssen PR, Pfutzenreuter D | Aktiengesellschaft |
| U.S. Pat. No. | Heath JR and Leff DV | The Regents |
| 6103868 | | of the |
| | | University of |
| | | California |
| U.S. Pat. No. | Lyen E A | |
| 6063176 | | |
| WO 00/20916 | Jacobson J, Hubert B, Ridley BA, | Massachu- |
| | Nivi B, Fuller S | setts Institute |
| | | of |
| | | Technology |
| U.S. Pat. No. | Kim K and Feng Q | The Board of |
| 5948483 | | Trustees of |
| | | the Univer- |
| | | sity of |
| | | Illinois |
| U.S. Pat. No. | Spanhel L, Arpac EA, Nab R, | Institut Fuer |
| 5470910 | Schmidt H | Neue |
| | | Materialien |
| | | GmbH |
| U.S. Pat. No. | Kim K, Ryu CK | The Board of |
| 5344676 | | Trustees of |
| | | the Univer- |
| | | sity of |
| | | Illinois |
| U.S. Pat. No. | Gruber, William C, Barringer EA, | Ceramics |
| 5062891 | | Process |
| | | Systems |
| | | Corporation, |
| | | Milford, MA |

### Other References

Alejandro-Arellano M, Ung T, Blanco A, Mulvaney P, Liz-Marzan LM Silica-coated metals and semiconductors. Stabilization and nanostructuring Pure and Applied Chemistry 72 257-267 (2000)

Ridley BA, Nivi B, Jacobson JM

All-inorganic field effect transistors fabricated by printing SCIENCE 286:5440 746-749 Oct. 22 (1999)

Brust M, Bethell D, Kiely CJ, Schiffin DJ, Self-assembled gold nanoparticle thin films with nonmetallic optical and electronic properties Langmuir 14: 19 5425-5429 Sep. 15 (1998)

Brust M, Bethell D, Schiffrin DJ, Kiely CJ Novel gold-dithiol nano-networks with nonmetallic electronic properties Adv. Mater. 7, 795 (1995)

Cassagneau T, Mallouk TE, Fendler JH Layer-by-layer assembly of thin film zener diodes from conducting polymers and CdSe nanoparticles Journal of the Chemical Society 120: (31) 7848-7859 Aug. 12 (1998)

Craighton JA, Blatchford GC, Albrecht MG J. Chem. Soc. Faraday Trans. 2 (75) 790 (1979)

Duff DG, Baiker A, Edwards PP A new hydrosol of gold clusters Journal of the Chemical Society-Chemical Communictaions, 1 96-98 JAN 7 (1993)

Fendler JH Self-assembled nanostructured materials Chemistry of Materials 8: (8) 1616-1624 Aug. (1996)

Giersig M, Mulvaney P Formation of ordered 2-dimensional gold colloid lattices by electrophoretic deposition J. Phys. Chem. 97 6334 (1993)

Greenham NC, Peng XG, Alivisatos AP Charge separation and transport in conjugated polymer cadmium selenide nanocrystal composites studied by photoluminescence quenching and photoconductivity Synthetic Metals 84: (1-3) 545-546 JAN (1997)

Fishelson N, Shkrob I, Lev 0, Gun J, Modestov AD Studies on charge transport in self-assembled gold-dithiol films: Conductivity, photoconductivity, and photoelectrochemical measurements Langmuir 17 (2): 403-412 JAN 23 (2001)

Hostetler MJ, Green SJ, Stokes JJ, Murray RW Monolayers in three dimensions: Synthesis and electrochemistry of omega-functionalized alkanethiolate-stabilized gold cluster compounds Journal of the American Chemical Society 118: (17) 4212-4213 MAY 1 (1996)

Leibowitz FL, Zheng WX, Maye MM, Zhong CJ Structures and properties of nanoparticle thin films formed via a one-step-Exchange-cross-linking-Precipitation route Analytical Chemistry 71: (22) 5076-5083 Nov. 15 (1999)

Musick MD, Pena DJ, Botsko SL, McEvoy TM, Richardson JN, Natan MJ, Electrochemical properties of colloidal Au-based surfaces: Multilayer assemblies and seeded colloid films Langmuir 15: (3) 844-850 Feb. 2 (1999)

Sandhyarani N, Antony MP, Selvam GP, Pradeep T Melting of monolayer protected cluster superlattices Journal of Chemical Physics 113 (21): 9794-9803 Dec. 1 2000

Sarathy KV, Raina G, Yadav RT, Kulkarni GU, Rao CNR Thiol-derivatized nanocrystalline arrays of gold, silver, and platinum Journal of Physical Chemistry B 101 (48): 9876-9880 Nov. 27 (1997)

Schlamp MC, Peng XG, Alivisatos AP Improved efficiencies in light emitting diodes made with CdSe(CdS) core/shell type nanocrystals and a semiconducting polymer Journal of Applied Physics 82: (11) 5837-5842 Dec. 1 (1997)

Schmid G, Lehnert A, Kreibig U, Adamczyk Z, Belouschek P

Synthesis and electron-microscopic investigations of controlled grown, ligand stabilized gold colloids and theoretical considerations on the covering of surfaces by colloids Z. Naturforsch. 45b, 989 (1990)

Shah P, Kevrekidis Y, Benzinger J Ink-Jet printing of Catalyst Patterns for Electroless Metal Deposition Langmuir 15, 1584-1587 (1999)

Templeton AC, Hostetler MJ, Warmoth EK, Chen SW, Hartshorn CM, Krishnamurthy VM, Forbes MDE, Murray RW Gateway reactions to diverse, polyfunctional monolayer-protected gold dusters Journal of the American Chemical Society 120: (19) 4845-4849 MAY 20 (1998)

Turkevich J, Stevenson PC, Hillier J Discuss. Faraday Soc. 11 55 (1951)

Wuelfing WP, Zamborini FP, Templeton AC, Wen XG, Yoon H, Murray RW Monolayer-protected clusters: Molecular precursors to metal films Chemistry of Materials 13 (1): 87-95 JAN (2001)

Yonezawa T, Kunitake T Practical preparation of anionic mercapto ligand-stabilized gold nanoparticles and their immobilization Colloids and Surfaces A-Physicochemical and Engineering Aspects 149 (1-3): 193-199 Apr. 15 (1999)

1-12. (cancelled).

13. A method for preparing stable sols of surface-modified nanoparticle aggregates, the methods comprising the steps of:
(i) producing a sol of nanoparticles;
(ii) adding at least one functionalising agent to the sol of nanoparticles;
(iii) allowing the nanoparticles and the at least one functionalising agent to react to form a sol of surface-modified nanoparticle aggregates; and
(iv) purifying the sol of surface-modified nanoparticle aggregates to obtain a purified sol of surface-modified nanoparticle aggregates in which the aggregates are of a size range of about 4 nm in diameter to about 10 μm in diameter.

14. A method according to claim 13 wherein the method of purifying the sol of surface-modified nanoparticle aggregates is selected from the group consisting of centrifugation, filtration, dialysis, and precipitation.

15. A method according to claim 13 wherein step (iv) comprises centrifuging the sol of surface-modified nanoparticle aggregates and resuspending the surface-modified nanoparticle aggregates.

16. A method according to claim 13 wherein the sol of surface-modified nanoparticle aggregates is concentrated by centrifugation.

17. A method according to claim 13 wherein at least one of the functionalising agents acts as a cross-linking agent.

18. A method according to claim 13 wherein the functionalising agent cross-links the nanoparticles into small aggregates and forms a protecting shell around these aggregates, separating the nanoparticles aggregates and preventing their further aggregation.

19. A method according to claim 13 wherein at least one of the functionalising agents is a cross-linking agent and at least one of the functionalising agents is a capping agent.

20. A method according to claim 19 wherein the cross-linking agent cross-links individual nanoparticles into small aggregates and the capping agent separates the nanoparticle aggregates preventing their further aggregation.

21. A method according to claim 13 wherein the nanoparticles are gold or silver.

22. A method of forming a coherent film comprising surface-modified nanoparticle aggregates, the method comprising depositing a sol of surface-modified nanoparticle aggregates produced according to the method of claim 13 onto a substrate.

23. A method according to claim 22 wherein the sol of surface-modified nanoparticle aggregates is deposited onto the substrate by printing, spraying, drawing, painting or electrodeposition.

24. A method according to claim 22 wherein the substrate is flexible.

25. An ink comprising a stable sol of surface-modified nanoparticle aggregates, the sol being produced by the method according to claim 13.
